(19) United States
(12) Patent Application Publication
(10) Pub. No.: US 2026/0040690 A1
(43) Pub. Date: Feb. 5, 2026

(54) APPARATUS INCLUDING SOI CMOS TRANSISTOR PAIR

(71) Applicant: MICRON TECHNOLOGY, INC., Boise, ID (US)

(72) Inventors: Takuya Imamoto, Tokyo (JP); Dan Mocuta, Boise, ID (US); Mark Fischer, Boise, ID (US); Durai Vishak Nirmal Ramaswamy, Boise, ID (US); Shivani Srivastava, Boise, ID (US); Srinivas Pulugurtha, Boise, ID (US)

(73) Assignee: MICRON TECHNOLOGY, INC., Boise, ID (US)

(21) Appl. No.: 19/280,782

(22) Filed: Jul. 25, 2025

Related U.S. Application Data
(60) Provisional application No. 63/677,564, filed on Jul. 31, 2024.

(51) Int. Cl. H10D 87/00; H01L 25/18; H10B 80/00; H10D 62/832; H10D 64/66; H10D 80/30

(52) U.S. Cl. CPC H10D 87/00; H10D 64/666; H10D 64/669; H01L 25/18; H10B 80/00; H10D 62/832; H10D 80/30

(57) ABSTRACT

Some embodiments of the disclosure provide an apparatus comprising a memory cell array region, and a peripheral region including a silicon-on-insulator (SOI) complementary metal-oxide-silicon (CMOS) transistor. The SOI CMOS transistor pair includes a buried oxide (BOX) layer in a semiconductor substrate, and an SOI layer on the BOX layer. The SOI layer has a thickness such that a depletion layer when formed in the SOI layer fills the SOI layer between a gate and the BOX layer and between source/drain regions.

### CROSS-REFERENCE TO RELATED APPLICATIONS

This application claims the filing benefit of U.S. Provisional Application No. 63/677,564, filed Jul. 31, 2024. This application is incorporated by reference herein in its entirety and for all purposes.

### BACKGROUND

High data reliability, high speed of memory access, low power consumption, and reduced chip size are some features that are demanded from semiconductor memory devices, such as a dynamic random-access memory (DRAM). Semiconductor memory devices may include various circuits, such as a sense amplifier, a subword driver, a control circuit, and an interface circuit. Such various circuits may use transistors, such as field-effect transistors (FETs). FETs may be complementary metal-oxide-semiconductor (CMOS) transistors.

### BRIEF DESCRIPTION OF THE DRAWINGS

FIG. 1 depicts an example configuration of at least part of a semiconductor device in a cross-sectional view according to an embodiment of the disclosure.

FIGS. 2A-2C illustrate example depletion regions in a bulk MOSFET, a partially-depleted (PD) SOI MOSFET, and a fully-depleted (FD) SOI MOSFET, respectively.

FIGS. 3-6 each depict an example configuration of at least part of a semiconductor device in a cross-sectional view according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

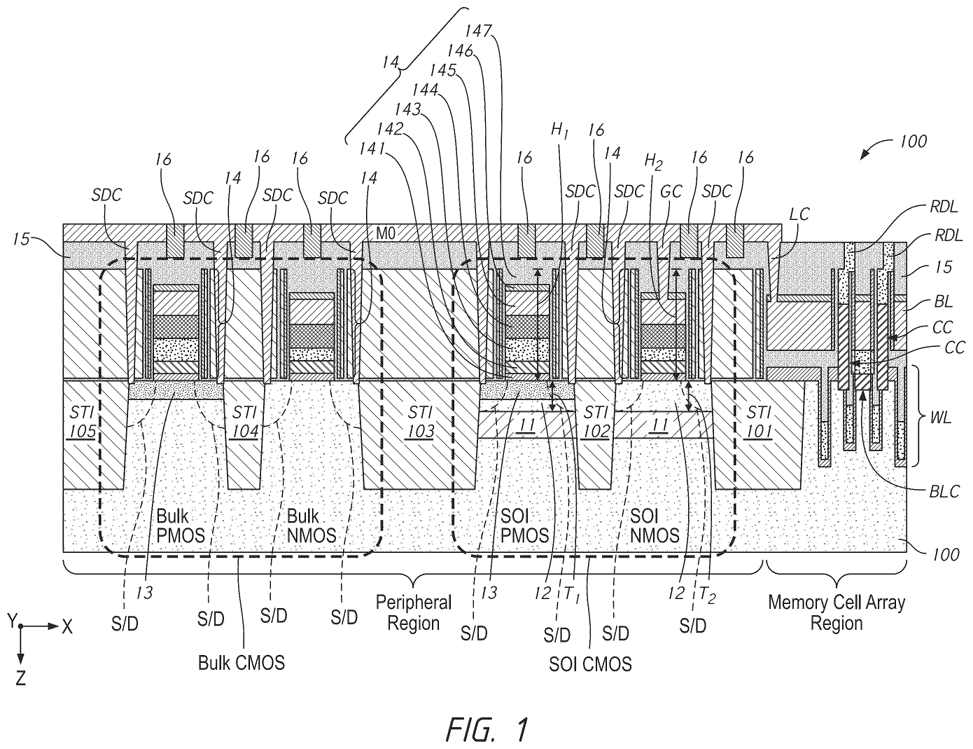

FIG. 1 depicts an example configuration of at least part of a semiconductor device 100 in a cross-sectional view according to an embodiment of the disclosure. The semiconductor device 100 may be a dynamic random-access memory (DRAM). The semiconductor device 100 may be one example of an apparatus. The semiconductor device 100 of FIG. 1 includes a memory cell array region and a peripheral region on a semiconductor substrate 10, such as a silicon substrate. The memory cell array region may include a plurality of memory cells arranged at intersections of word lines WL and bit lines BL. The word lines WL may be arranged in parallel with each other in one horizontal direction (for example, an X-axis direction in the drawing) and each may extend in another horizontal direction (for example, a Y-axis direction perpendicular to the X-axis direction in the drawing). The bit lines BL may be arranged in parallel with each other in the Y-axis direction and each may extend in the X-axis direction. The bit lines BL may be coupled to a metal layer MO by a local contact LC. The local contact LC vertically extends through one or more layers 15 (such as an insulating layer and a SiN layer) above the bit lines BL and is coupled to the bit lines BL at one end and the metal layer MO at another end. The metal layer MO may be provided above transistors in the peripheral region and coupled to source/drain regions (S/D) of the semiconductor substrate 10 by source/drain contacts SDC and to transistor gates by gate contacts GC in the peripheral region. The bit lines BL and the metal layer MO as well as the various contacts may include a conductive material, such as tungsten W. The memory cell array region may also include bit line contacts BLC, cell contacts CC, and redistribution layers RDL. The memory cell array region may further include a plurality of memory cell capacitors (not separately illustrated in the drawing) that are formed above the corresponding redistribution layers RDL, which couple the cell contacts CC and the memory cell capacitors. The redistribution layer RDL may include a conductive material, such as titanium nitride (TiN) and tungsten (W). The memory cell array region may include other elements as appropriate. The memory cell array region may have a square shape or a rectangular shape in a plan view (for example, in a plane along the X-axis direction and the Y-axis direction) on the semiconductor substrate 10. The peripheral region may be provided adjacent to the memory cell array region in the X-axis direction and/or the Y-axis direction. The peripheral region may be provided around the memory cell array region in the plan view on the semiconductor substrate 10. A shallow trench isolation (STI) 101 may be provided between the memory cell array region and the peripheral region. The STI 101 may include an insulating material, such as silicon oxide (SiO) and silicon nitride (SiN). The peripheral region may also include interlayer dielectric films 16 (including, for example, SiN, SiO, silicon oxycarbide SiOC, or silicon oxycarbonitride SiOCN) penetrating through the metal layer MO and reaching partway the underlying layer 15 at appropriate positions.

In the example configuration, the peripheral region includes a silicon-on-insulator (SOI) complementary metal-oxide-semiconductor (CMOS) transistor pair. The SOI CMOS transistor pair may be selectively arranged at an appropriate position in the peripheral region. The SOI CMOS transistor may be arranged adjacently to the memory cell array region. The SOI CMOS transistor pair may be separated from the memory cell array region by the STI 101. The SOI CMOS transistor may be separated from the memory cell structures in the memory cell array region by the STI 101.

In the example configuration, there is a bulk CMOS transistor pair arranged adjacently to the SOI CMOS transistor pair. The bulk CMOS transistor pair may be any conventional bulk CMOS transistor pair as appropriate. The bulk CMOS transistor pair includes a bulk P-channel MOS (PMOS) transistor and a bulk N-channel MOS (NMOS) transistor. The bulk PMOS transistor and the NMOS transistor each may be a MOS field-effect transistor (FET). The bulk PMOS transistor and the bulk NMOS transistor are separated by an STI 104 provided therebetween. The bulk PMOS transistor and the bulk NMOS transistor each include, for example, a gate stack structure 14. In some instances, the bulk PMOS transistor may include a silicon germanium (SiGe) layer 13. In other instances, the bulk PMOS transistor may not include a silicon germanium (SiGe) layer 13. The metal layer MO is coupled to source/drain regions in the semiconductor substrate 10 via source/drain contacts SDC. The SOI CMOS transistor pair and the bulk CMOS transistor pair may be separated by an STI 103 from each other. In some instances, there may be other transistors adjacent to the bulk CMOS transistors with an STI 105 therebetween. In some instances, there may be other transistors, such as bipolar transistors, than the bulk CMOS transistors adjacent to the SOI CMOS transistor pair. In some instances, there may be no other transistors adjacent to the SOI CMOS transistor pair. In still some instances, there may be a plurality of SOI CMOS pairs in the peripheral region. The arrangement of transistors in the peripheral region may depend on device designs, specifications, and the like. In the peripheral region, various circuits, such as a sense amplifier, a subword driver, a control circuit, and an interface circuit, may be provided. Such various circuits may use the SOI CMOS transistor pair, the bulk CMOS transistor pair, and the like.

The SOI CMOS transistor pair includes an SOI P-channel MOS (PMOS) transistor and an SOI N-channel MOS (NMOS) transistor. The SOI PMOS transistor and the SOI NMOS transistor each may be a MOS field-effect transistor (FET). The SOI PMOS transistor and the SOI NMOS transistor are separated by an STI 102 provided therebetween. Each of the SOI PMOS transistor and the SOI NMOS transistor includes a buried oxide (may also be referred to as a BOX) layer 11 in the semiconductor substrate 10, and a silicon layer (may also be referred to as an SOI layer) 12 on the BOX layer 11. The BOX layer 11 is a thin layer of an insulator formed on top of base silicon of the semiconductor substrate 10. The SOI layer 12 is a thin silicon layer formed on the BOX layer 11 to implement a transistor channel between one of source/drain regions S/D and another of the source/drain regions S/D formed above the BOX layer 11. A gate stack structure 14 is then provided on the transistor channel of the SOI layer 12.

As one example of device forming processes, the BOX layer 11 may first be formed at an appropriate position in the semiconductor substrate 10. The SOI layer 12 may then be formed on the BOX layer 11. Afterwards, the STIs may be formed in the semiconductor substrate 10. As another example, a silicon germanium (SiGe) layer (which is different from the SiGe layer 13 described above) and a silicon (Si) layer may first be formed at positions where the BOX layer 11 and the SOI layer 12 will be arranged on the semiconductor substrate 10, respectively. The STIs may then be formed at appropriate positions. Subsequently, the SiGe layer under the Si layer (or the SOI layer 12) may be removed by, for example, selective wet etching or vapor etching, and the removed space is filled with an oxide material to form the BOX layer 11 under the SOI layer 12. The removal process may also be referred to as an exhume process. The oxide material may be provided to the removed space by, for example, oxidation (dry or wet) and/or oxide deposition (such as atomic layer deposition ALD, chemical vapor deposition CVD, and spin on dielectrics SOD). During the above processes, a thickness of the SOI layer 12 may be adjusted by, for example, epitaxial growth of Si on the BOX layer 11. Si thickness on the SiGe layer (that is Si/SiGe formed by epitaxial growth) may be adjusted by the selective SiGe etching and the oxide material provision upon formation of the BOX layer 11 under the SOI layer 12. Si thickness may also be adjusted by oxidation of the SOI layer 12 followed by an oxide etching process, such as wet etching or vapor etching. During the removal process (or the exhume process) of the SiGe layer under the Si layer, the selective etching process may be split to more than two steps to achieve different SOI thicknesses among the devices (between the SOI NMOS transistor and the SOI PMOS transistor, for instance) in the same wafer. Alternatively, multiple SOI thicknesses may be provided by different Si/SiGe layer thicknesses prior to the selective etching process.

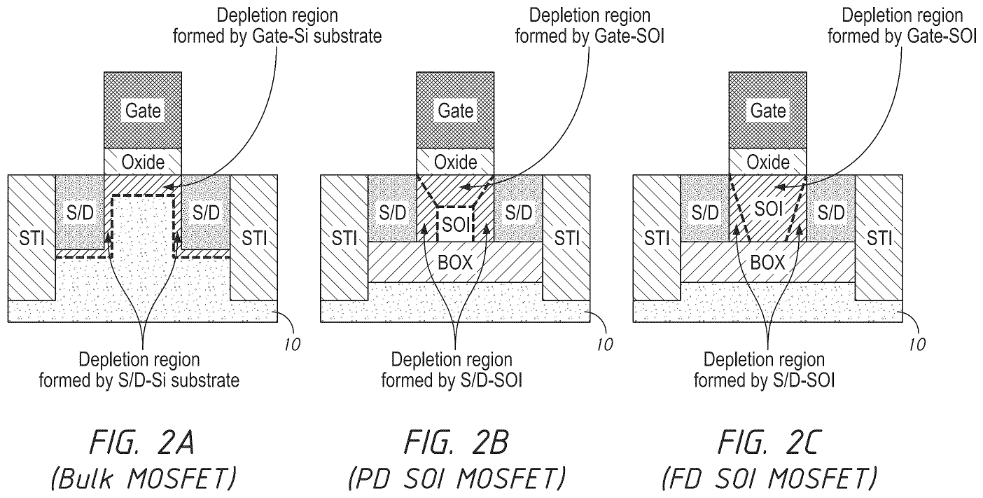

According to the present embodiment, the SOI layer 12 may have a thickness such that a depletion layer when formed in the SOI layer 12 fills the SOI layer 12 between the gate stack structure 14 and the BOX layer 11 and between the source/drain regions S/D. A depletion layer when formed may reach the BOX layer 11 from the gate stack structure 14 through the SOI layer 12 in a vertical direction (for example, a Z-axis direction in the drawing). The SOI layer 12 having such a thickness may operate as a fully-depleted device. FIGS. 2A-2C illustrate example depletion regions in a bulk MOSFET, a partially-depleted (PD) SOI MOSFET, and a fully-depleted (FD) SOI MOSFET, respectively. In each figure, for the sake of ease of explanation, the gate stack structure is simplified, and the size, the shape, etc. of each part do not match those in the configuration depicted in FIG. 1. In each MOSFET, the depletion layer may include a depletion region which forms under the gate and depletion regions which forms between the source/drain regions S/D; however, in the bulk MOSFET (FIG. 2A) and the PD MOSFET (FIG. 2B), both the depletion region in the direction from the gate to the semiconductor substrate 10 or the SOI layer (SOI) and the depletion regions in the direction from the source/drain regions S/D to the semiconductor substrate 10 or the SOI layer (SOI) may extend only to the extent depending on channel dopant concentration (that is the substrate dopant concentration in the bulk MOSFET or the SOI dopant concentration in the PD MOSFET), whereas in the FD MOSFET (FIG. 2C), the depletion region from the gate extends through the SOI layer until it reaches the BOX layer (BOX). Hence, the SOI layer surrounded by the gate or the gate stack structure and the source/drain regions S/D above the BOX layer is filled with the depletion layer including the above depletion regions. According to the present embodiment, the SOI layer may be adjusted to be sufficiently thin such that the thickness thereof becomes at least equal to the thickness of the depletion layer between the gate stack structure and the BOX layer. According to the present embodiment, the dopant concentration of the SOI layer may also be adjusted to be sufficiently small to achieve the above thickness relation between the SOI layer and the depletion layer. In some instances, there may be no dopants in the SOI layer, but with the sufficiently thin thickness of the SOI layer, the depletion layer may form to entirely occupy the SOI layer between the gate stack structure and the BOX layer and between the source/drain regions.

Referring back to FIG. 1, in the example configuration, the SOI PMOS transistor further includes a silicon germanium (SiGe) layer 13. As one example, after the SOI layer 12 is formed on the BOX layer 11, germanium or a material including germanium is provided on an upper surface of the SOI layer 12 and is mixed with the silicon of the SOI layer 12 by, for example, a heating process, and the SiGe layer 13 is grown on the SOI layer 12. The SiGe layer 13 is provided to improve characteristics of the SOI PMOS transistor. In some instances, since the SOI layer 12 is thin, that is a space between an upper surface of the BOX layer 11 and a lower surface of the gate stack structure 14 is thin, the SiGe layer 13 may be grown to fill the space. The SOI layer 12 may thus become the SiGe layer 13. In another embodiment, the SiGe layer 13 may not be provided. According to the present embodiment, the SOI layer 12 and the SiGe layer 13 together may have thickness T₁ in the vertical direction such that the depletion layer when formed fills the SOI layer 12 and the SiGe layer 13 between the gate stack structure 14 and the BOX layer 11 and between the source/drain regions S/D. In one instance, the thickness T₁ of the SOI layer 12 including the SiGe layer 13 of the SOI PMOS transistor may be the same (or substantially the same within reasonable tolerances of fabrication, measurement, etc.) as thickness T₂ of the SOI layer 12 of the SOI NMOS transistor. In another instance, the thickness T₁ may be greater than the thickness T₂. In still another instance, the thickness T₂ may be greater than the thickness T₁.

In the SOI PMOS transistor, the gate stack structure 14 is provided on the SiGe layer 13 while in the SOI NMOS transistor, the gate stack structure 14 is provided on the SOI layer 12. In the example configuration, each gate stack structure 14 includes an interfacial layer 141 (including, for example, silicon dioxide SiO₂ or silicon oxynitride SiON), a high-k dielectric layer 142 (including, for example, hafnium oxide HfO, hafnium oxynitride HfON, hafnium silicate HfSiO, or hafnium silicon oxynitride HfSiON), a metal gate layer 143 (including, for example, titanium nitride TiN, lanthanum La, aluminum Al, or tantalum nitride TaN), a polycrystalline silicon (or polysilicon) layer 144, a metal layer 145 (including, for example, W), a dielectric interlayer 146 (including, for example, silicon nitride SiN, silicon monoxide SiO, silicon oxycarbide SiOC, or silicon oxycarbonitride SiOCN), and an insulating layer 147 (including, for example, SiN) stacked on one another in that order above the SOI layer 12 or the SiGe layer 13. In the case where T₁ is greater than T₂, H₁ of the PMOS gate stack structure 14 may be adjusted to be shorter than H₂ of the NMOS gate stack structure 14 so that a top surface of the PMOS gate stack structure 14 is aligned with a top surface of the NMOS gate stack structure 14. For instance, while the metal gate layer 143 of the PMOS gate stack structure 14 is thicker than that of the NMOS gate stack structure 14, the insulating layer 147 of the PMOS gate stack structure 14 is thinner than that of the NMOS gate stack structure 14.

In the case of the sense amplifier using a bulk CMOS transistor pair, there may be a fluctuation in transistor threshold voltage Vt, which may cause an issue in reading data from the bit lines. Furthermore, there may be leakage current (may also be referred to as a gate induced drain leakage GIDL) at the PN junction between the source/drain region and the neighboring region of the semiconductor substrate during a standby mode of a semiconductor device, such as a DRAM. Still furthermore, there may be a diffusion capacitance between the neighboring source/drain regions of the PMOS transistor and the NMOS transistor due to a shorter STI width between the PMOS and NMOS transistors. This may cause a coupling noise between the two transistors of the CMOS transistor pair. On the other hand, the SOI CMOS transistor pair according to the present embodiment improves the gate controllability and a short channel effect (SCE), and hence can effectively reduce the fluctuation in Vt and mitigate errors in reading data from the bit lines BL. This achieves a better noise margin of various circuits, such as sense amplifiers that utilize the SOI CMOS transistor pair of the present embodiment. Furthermore, according to the present embodiment, each of the SOI CMOS transistors separates the source/drain regions formed in the SOI layer 12 from the other regions of the semiconductor substrate 10 by the BOX layer 11 and hence can eliminate the leakage current at the PN junction in the semiconductor substrate 10. Still furthermore, according to the present embodiment, each of the SOI CMOS transistors has shallow source/drain regions that stop at the BOX layer 11 such that electrons flowing through a channel between the source and drain regions are confined in the space above the BOX layer 11. For example, the thickness of the SOI layer 12 on the BOX layer 11 (that is the thickness from the SOI channel surface to the BOX layer 11) in the Z-direction in FIG. 1 may be, for example, in the range of about 1 nm to about 10+ nm, or in the range of about 7 nm to about 10 nm, and hence the source/drain regions confined above the BOX layer 11 in the SOI CMOS transistors are much thinner than the source/drain regions in the bulk CMOS transistors which may have the thickness of, for example, about 100 nm. Hence, the area of the coupling between the neighboring source/drain regions through the STI and hence the diffusion capacitance therebetween are reduced. This way, the coupling noise induced by the diffusion capacitance can be effectively minimized. This further improves noise margin of various circuits, such as sense amplifiers that use the SOI CMOS transistor pair.

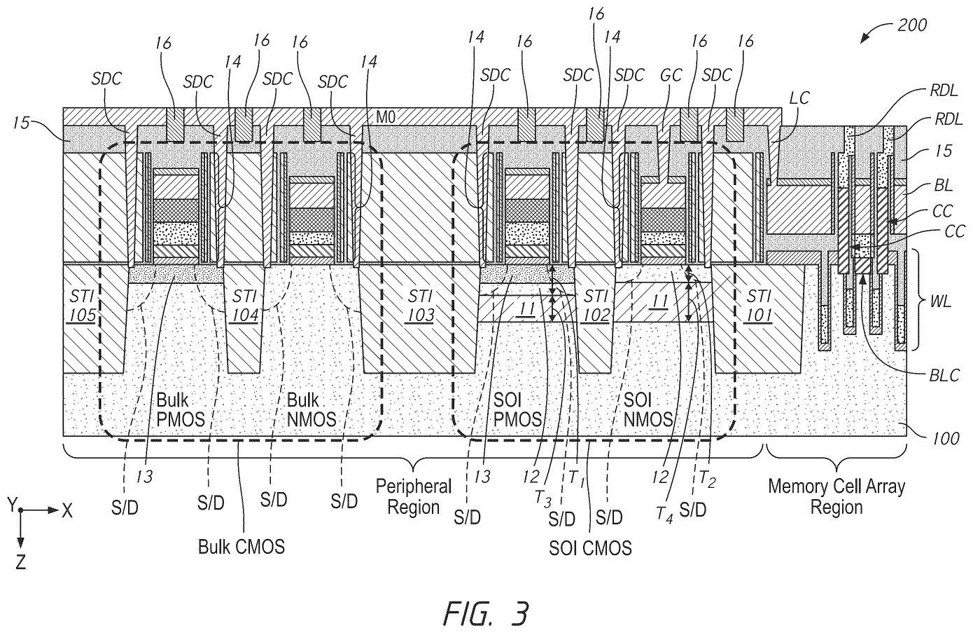

FIG. 3 depicts an example configuration of at least part of a semiconductor device 200 in a cross-sectional view according to an embodiment of the disclosure. While FIG. 1 shows the case where the thickness T₁ of the SOI layer 12 including the SiGe layer 13 above the BOX layer 11 of the SOI PMOS transistor is the same or substantially the same as the thickness T₂ of the SOI layer 12 of the SOI NMOS transistor, FIG. 3 shows the case where T₁ is greater than T₂. As described above, the thickness of each of the SOI layers 12 can be adjusted during the formation of the BOX layers 11 and the SOI layers 12 of both the SOI PMOS transistor and the SOI NMOS transistor. In one instance, during the removal/exhume process of the SiGe layer under the Si layer described above, while masking the SOI NMOS side by using a first hard mask (which may also be referred to as a first exhume mask), a first step of the selective etching may be performed to the SOI PMOS side to achieve a thickness T₃ of the BOX layer 11, which in turn provides the thickness T₁ of the SOI layer 12 in the SOI PMOS transistor. Subsequently, while masking the SOI PMOS side by using a second hard mask (which may also be referred to as a second exhume mask), a second step of the selective etching may be performed to the SOI NMOS side to achieve a thickness T₄ of the BOX layer 11, which in turn provides the thickness T₂ of the SOI layer 12 in the SOI NMOS transistor. During this two-step process, the first step is performed to remove the SiGe layer under the Si layer such that the removed area becomes the BOX layer 11 (after it is filled with the oxide material) having the thickness T₃ whereas the second step is performed for a longer period of time than the first step to remove the SiGe layer and part of the Si layer such that the removed area becomes the BOX layer 11 (after it is filled with the oxide material) having the thickness T₄ greater than T₃. This thins down the SIO layer 12 above the BOX layer 11 in the SOI NMOS transistor, achieving T₁>T₂. In another instance, T₁>T₂ may be obtained by other processes prior to the above selective etching steps. The thicknesses of the BOX layers 11 and the SOI layers 12 may be determined based on device designs, specifications, and the like. The detailed descriptions of the configuration, elements, and the like of the semiconductor device 200 that are the same or substantially the same as those of the semiconductor device 100 are omitted here.

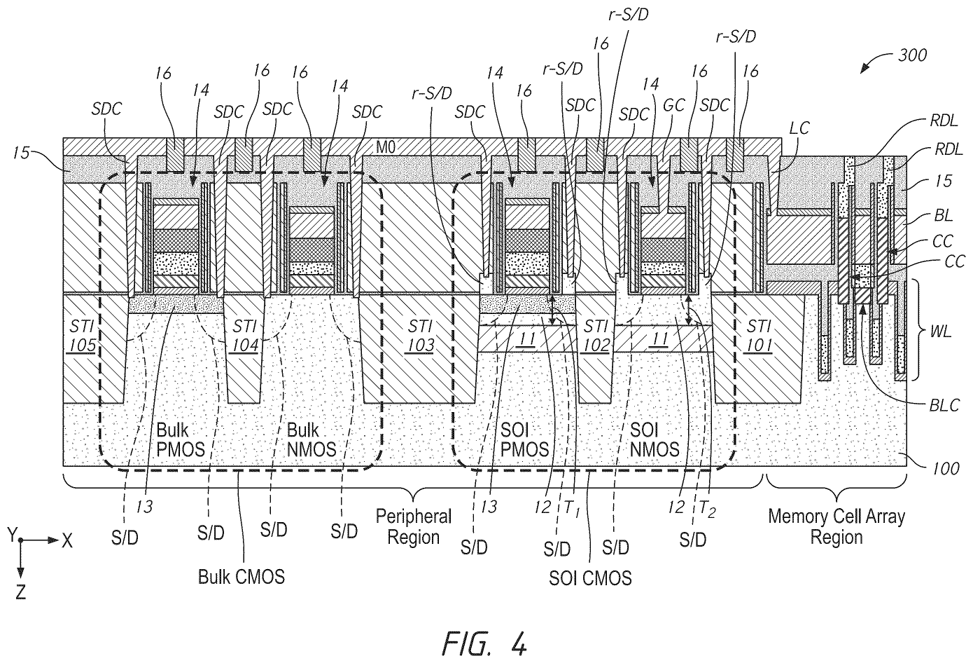

FIG. 4 depicts an example configuration of at least part of a semiconductor device 300 in a cross-sectional view according to an embodiment of the disclosure. In the semiconductor device 300, the SOI PMOS transistor and the SOI NMOS transistor each include raised source/drain regions r-S/D. The raised source/drain regions r-S/D may include the same materials as or different materials from those used in the source/drain regions S/D in the SOI layer 12 above the BOX layer 11. Examples of such materials may include but are not limited to silicon (Si), silicon phosphide (SiP), silicon germanium (SiGe), silicon germanium boron (SiGeB), silicon carbide (SiC), and silicon carbide phosphide (SiCP). The raised source/drain regions r-S/D may be formed by, for example, selective epitaxial growth of the above materials on the SiGe layer 13 in the SOI PMOS transistor or on the SOI layer 12 in the SOI NMOS transistor. Ion plantation may also be used optionally. Each of the raised source/drain regions r-S/D extends vertically (in the Z-axis direction in the drawing) and is formed adjacently to the gate stack structure 14. Conditions of the selective epitaxial growth and/or the ion plantation may be determined to achieve a height (or a thickness in the Z-axis direction), a shape, and the like of the raised source/drain region r-S/D, which may be determined based on device designs, specifications, and the like. In the example configuration of FIG. 4, the source/drain contacts SDC arranged adjacently to the gate stack structures 14 may be made shorter than those in the example configuration of FIG. 1 to reach corresponding upper portions of the raised source/drain regions r-S/D. In some instances, at least one of the SOI PSMO transistor or the SOI NMOS transistor of the SOI CMOS transistor pair may include the configuration of the raised source/drain regions r-S/D. In some instances, the configuration of the raised source/drain regions r-S/D may also be applied to the bulk CMOS transistor pair. The detailed descriptions of the configuration, elements, and the like of the semiconductor device 300 that are the same or substantially the same as those of the semiconductor device 100 are omitted here.

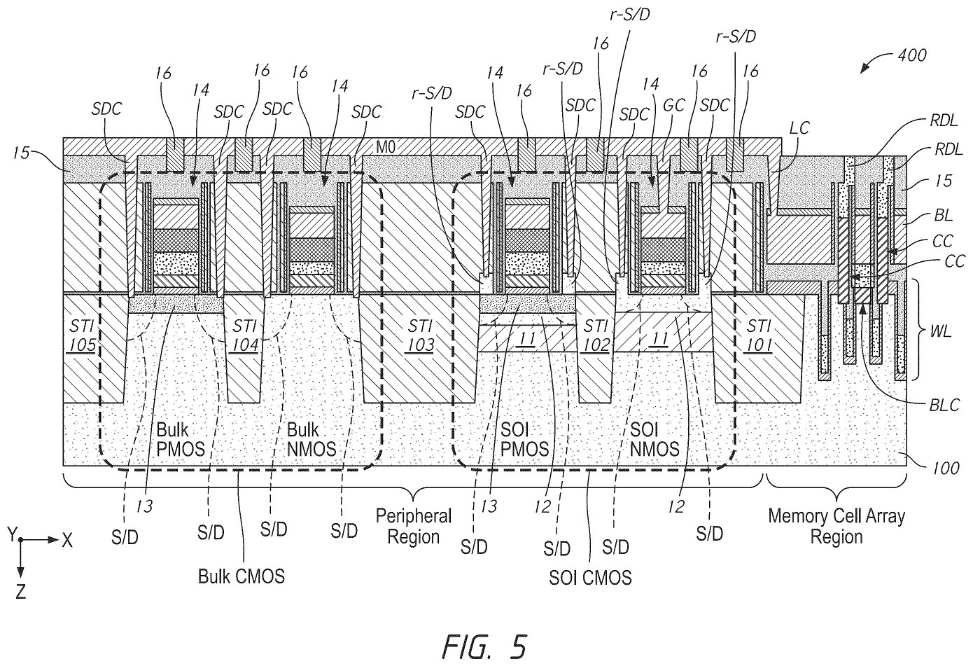

FIG. 5 depicts an example configuration of at least part of a semiconductor device 400 in a cross-sectional view according to an embodiment of the disclosure. The semiconductor device 400 includes both the configuration of the multiple SOI thicknesses in FIG. 3 and the configuration of the raised source/drain regions r-S/D in FIG. 4. The detailed descriptions of the configuration, elements, and the like of the semiconductor device 400 that are the same or substantially the same as those of the semiconductor devices 100, 200, and 300 are omitted here.

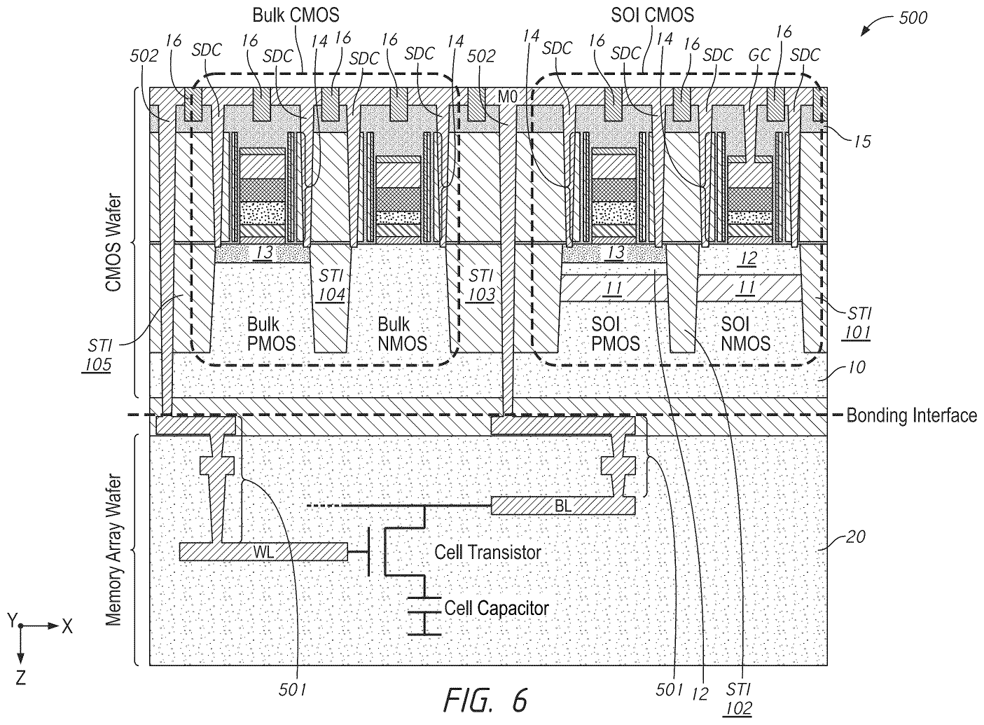

FIG. 6 depicts an example configuration of at least part of a semiconductor device 500 in a cross-sectional view according to an embodiment of the disclosure. The semiconductor device 500 has a wafer-to-wafer configuration that includes a CMOS wafer and a memory array wafer bonded together. The CMOS wafer and the memory array wafer are adjacent to each other in the Z-axis direction. The CMOS wafer and the memory array wafer may correspond to the peripheral region and the memory cell array region of the semiconductor devices 100, 200, 300, and 400, respectively. In the semiconductor device 500, the CMOS wafer and the memory array wafer may be regarded as the peripheral region and the memory cell array region, respectively. The CMOS wafer includes a plurality of CMOS transistor pairs formed on the semiconductor substrate 10. The memory cell array wafer includes a plurality of memory cells formed on another semiconductor substrate 20. The CMOS transistor pairs in the CMOS wafer may include various CMOS transistor pairs, such as the bulk CMOS transistor pair and the SOI CMOS transistor pair according to the present embodiments described above. The bulk CMOS transistor pair and the SOI CMOS transistor pair depicted in FIG. 6 are the same or substantially the same as those depicted in FIG. 1. Each memory cell in the memory array wafer includes a cell capacitor and a cell transistor coupled to a corresponding bit line BL and a corresponding word line WL. The bit line BL and the word line WL in the memory array wafer are further coupled to, for example, the metal layer MO in the CMOS wafer by conductive paths 501 and 502 including conductive layers, conductive pads, conductive vias, and the like that extend through the two bonded wafers. The CMOS wafer and the memory array wafer are separately prepared, and then are bonded together by a conventional wafer-to-wafer bonding method. The two wafers may be bonded in a front-to-back bonding manner, a back-to-back bonding manner, and the like at a bonding interface. The conductive paths 501 and 502 extend through the bonding interface between the two wafers.

One example of the semiconductor devices 100, 200, 300, 400, and 500 may be a DRAM. However, a DRAM is merely one example, and the embodiments and the descriptions herein are not intended to be limited to a DRAM. Memory devices other than a DRAM, such as a static random-access memory (SRAM), a flash memory, an erasable programmable read-only memory (EPROM), a magnetoresistive random-access memory (MRAM), and a phase-change memory, can also be applied as the semiconductor devices 100, 200, 300, 400, and 500. Furthermore, devices other than memory devices, including logic ICs, such as a microprocessor and an application-specific integrated circuit (ASIC), are also applicable as the semiconductor device according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a memory cell array region; and
a peripheral region including a silicon-on-insulator (SOI) complementary metal-oxide-silicon (CMOS) transistor pair, wherein
the SOI CMOS transistor pair includes a buried oxide (BOX) layer in a semiconductor substrate, and an SOI layer on the BOX layer, and
the SOI layer has a thickness such that a depletion layer when formed in the SOI layer fills the SOI layer between a gate and the BOX layer and between source/drain regions.

2. The apparatus according to claim 1, wherein the SOI layer has the thickness such that the depletion layer when formed reaches the BOX layer from the gate.

3. The apparatus according to claim 1, wherein the SOI CMOS transistor pair includes a gate stack structure on the SOI layer.

4. The apparatus according to claim 1, wherein the BOX layer is configured to separate source/drain regions formed in the SOI layer from other regions of the semiconductor substrate.

5. The apparatus according to claim 1, wherein the SOI CMOS transistor pair further includes a raised source/drain region.

6. The apparatus according to claim 1, wherein the SOI CMOS transistor pair further includes a silicon germanium (SiGe) layer on the SOI layer, and the SOI layer and the SiGe layer together have the thickness such that the depletion layer when formed fills the SOI layer and the SiGe layer.

7. The apparatus according to claim 6, wherein the SOI CMOS transistor pair includes a gate stack structure on the SiGe layer.

8. The apparatus according to claim 1, wherein the SOI CMOS transistor pair includes an SOI P-channel metal-oxide-silicon (PMOS) transistor and an SOI N-channel MOS (NMOS) transistor and includes a shallow trench isolation between the SOI PMOS transistor and the SOI NMOS transistor.

9. The apparatus according to claim 8, wherein each of the SOI PMOS transistor and the SOI NMOS transistor includes the SOI layer on the BOX layer and a gate stack structure on the SOI layer.

10. The apparatus according to claim 9, wherein a first thickness of the SOI layer of the SOI PMOS transistor is greater than a second thickness of the SOI layer of the SOI NMOS transistor.

11. The apparatus according to claim 1, wherein the peripheral region includes a sense amplifier, and the sense amplifier includes the SOI CMOS transistor pair.

12. The apparatus according to claim 1, further including a bulk CMOS transistor pair adjacent to the SOI CMOS transistor pair.

13. An apparatus, comprising:
a memory cell array region; and
a peripheral region including a silicon-on-insulator (SOI) complementary metal-oxide-silicon (CMOS) transistor pair, the SOI CMOS transistor pair including an SOI P-channel metal-oxide-silicon (PMOS) transistor and an SOI N-channel MOS (NMOS) transistor, wherein
each of the SOI PMOS transistor and the SOI NMOS transistor includes a buried oxide (BOX) layer in a semiconductor substrate and an SOI layer on the BOX layer,
the SOI layer of the SOI PMOS transistor includes a silicon germanium (SiGe) layer, and the SOI layer and the SiGe layer together have a first thickness such that a first depletion layer when formed fills the SOI layer and the SiGe layer between a PMOS transistor gate and the BOX layer and between PMOS transistor source/drain regions, and
the SOI layer of the SOI NMOS transistor has a second thickness such that a second depletion layer when formed fills the SOI layer between an NMOS transistor gate and the BOX layer and between NMOS transistor source/drain regions.

14. The apparatus according to claim 13, wherein
the SOI layer of the SOI PMOS transistor has the first thickness such that the first depletion layer when formed includes a first depletion region that reaches the BOX layer from the PMOS transistor gate, and
the SOI layer of the SOI NMOS transistor has the second thickness such that the second depletion layer when formed includes a second depletion region that reaches the BOX layer from the NMOS transistor gate.

15. The apparatus according to claim 13, wherein the first thickness of the SOI layer of the SOI PMOS transistor is greater than the second thickness of the SOI layer of the SOI NMOS transistor.

16. The apparatus according to claim 13, wherein the SOI PMOS transistor includes a first gate stack structure on the SiGe layer, and the SOI NMOS transistor includes a second gate stack structure on the SOI layer.

17. The apparatus according to claim 13, wherein at least one of the SOI PMOS transistor or the SOI NMOS transistor includes a raised source/drain region.

18. An apparatus, comprising:
a silicon-on-insulator (SOI) complementary metal-oxide-silicon (CMOS) transistor pair on a first semiconductor substrate; and
a memory cell array on a second semiconductor substrate,
wherein the SOI CMOS transistor pair includes:
a buried oxide (BOX) layer in the first semiconductor substrate;
an SOI layer on the BOX layer; and
a gate stack structure on the SOI layer, and
wherein the SOI layer has a thickness such that a depletion layer when formed in the SOI layer fills the SOI layer between the gate stack structure and the BOX layer and between source/drain regions.

19. The apparatus according to claim 18, wherein
the SOI CMOS transistor pair includes an SOI P-channel metal-oxide-silicon (PMOS) transistor and an SOI N-channel MOS (NMOS) transistor and includes a shallow trench isolation between the SOI PMOS transistor and the SOI NMOS transistor, and
each of the SOI PMOS transistor and the SOI NMOS transistor includes the SOI layer on the BOX layer and the gate stack structure on the SOI layer.

20. The apparatus according to claim 19, wherein
the SOI layer of the SOI PMOS transistor has a first thickness such that the depletion layer when formed includes a first depletion region that reaches the BOX layer from the gate stack structure of the SOI PMOS transistor, and
the SOI layer of the SOI NMOS transistor has a second thickness such that the depletion layer when formed includes a second depletion region that reaches the BOX layer from the gate stack structure of the SOI NMOS transistor.
